(19) United States
(12) Patent Application Publication
(10) Pub. No.: US 2024/0141497 A1
(43) Pub. Date: May 2, 2024

(54) DIELECTRIC FILM SURFACE RESTORATION WITH REDUCTIVE PLASMA

(71) Applicant: Applied Materials, Inc., Santa Clara, CA (US)

(72) Inventors: Liang Song, Santa Clara, CA (US); Chengyu Liu, San Jose, CA (US)

(73) Assignee: Applied Materials, Inc., Santa Clara, CA (US)

(21) Appl. No.: 17/973,991

(22) Filed: Oct. 26, 2022

(51) Int. Cl. C23C 16/50; C23C 16/40; G03F 1/24

(52) U.S. Cl. CPC C23C 16/50; C23C 16/407; G03F 1/24

(57) ABSTRACT

Methods for forming an EUV photoresist hard mask are provided. The method includes treating a metal-rich layer on a substrate with a reductive plasma to form a metallic surface on the metal-rich layer, the metal-rich layer having a top portion comprising a metal oxide layer. The metal-rich layer comprises one or more of tin (Sn), indium (In), gallium (Ga), zinc (Zn), tellurium (Te), antimony (Sb), nickel (Ni), titanium (Ti), aluminum (Al), tantalum (Ta), bismuth (Bi), and lead (Pb).

### TECHNICAL FIELD

The present disclosure relates generally to methods of forming EUV hardmasks. In particular, the disclosure relates to methods to form EUV hardmasks comprising high Z metals.

### BACKGROUND

Reliably producing submicron and smaller features is one of the key requirements of very large-scale integration (VLSI) and ultra-large-scale integration (ULSI) of semiconductor devices. With the continued miniaturization of circuit technology, however, the dimensions of the size and pitch of circuit features, such as interconnects, have placed additional demands on processing capabilities. The multilevel interconnects that lie at the heart of this technology require precise imaging and placement of high aspect ratio features. Reliable formation of these interconnects is needed to further increases in device and interconnect density.

One process used to form various interconnect and other semiconductor features uses EUV (extreme ultraviolet) lithography. Conventional EUV patterning uses a multilayer stack in which a photoresist is patterned on top of a hardmask. Common hardmask materials are spin-on silicon anti-reflective coating (SiARC) and a deposited silicon oxynitride (SiON). The SiARC incorporates organic content to a silicon backbone, maintaining sufficient etch selectivity to the photoresist and underlying stack. Scaling the thickness of the SiARC backbone can be challenging and spin coating limits the minimum thickness that can be achieved without too many defects. The SiON hardmask uses an organic adhesion layer (OAL) for improved resist adhesion. The OAL prevents poisoning from nitrogen and is able to be reworked.

Several metal and metal oxide materials, e.g., high Z materials, have been tested as EUV hardmasks (HM). Due to their chemistry, high Z films tends to react with oxygen and get oxidized in air over time. There is currently no efficient way to prevent this spontaneous surface oxidation and no feasible way to restore the high Z film surface. Due to this issue, it is hard to control dose-to-size for EUV exposure as well as to predict corresponding EUV lithography performance such as critical dimension (CD) and line width roughness (LWR).

There is an ongoing need in the art, therefore, for methods for restoring the high Z surface.

### SUMMARY

One or more embodiments of the disclosure are directed to methods of forming an EUV photoresist hardmask. The methods comprise treating a metal-rich layer on a substrate with a reductive plasma to form a metallic surface on the metal-rich layer, the metal-rich layer having a top portion comprising a metal oxide layer.

Additional embodiments of the disclosure are directed to methods of forming an EUV photoresist hardmask. In one or more embodiments, a method of forming an EUV photoresist hard mask, the method comprises: forming a metal-rich layer on a substrate, the metal rich layer having a thickness in a range of from 10 Å to 50 Å; the metal-rich layer having a top portion comprising a metal oxide layer with a thickness in a range of from 20 Å to 100 Å; and treating the metal-rich layer with a reductive plasma to form a metallic surface on the metal-rich layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a method of depositing a film on a substrate according to one or more embodiments;

FIG. 2A illustrates a cross-section view of a substrate according to one or more embodiments;

FIG. 2B illustrates a cross-section view of a substrate according to one or more embodiments;

FIG. 2C illustrates a cross-section view of a substrate according to one or more embodiments; and

FIG. 2D illustrates a cross-section view of a substrate according to one or more embodiments.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of about.

As used in this specification and the appended claims, the term “substrate” or “wafer” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” or “substrate surface”, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used herein, “extreme UV”, “EUV”, or the like, refers to radiation in the approximate range of 10 nm to 124 nm. In some embodiments, EUV radiation (also referred to as EUV light) in the range of 10 nm to 15 nm. In one or more embodiments, EUV light at a wavelength of about 13.5 nm is employed.

As used in this specification and the appended claims, the terms “precursor,” “reactant,” “reactive gas” and the like are used interchangeably to refer to any gaseous species that can react with the substrate surface.

As used in this specification and the appended claims, the terms “reactive compound”, “reactive gas”, “reactive species”, “precursor”, “process gas” and the like are used interchangeably to mean a substance with a species capable of reacting with the substrate or material on the substrate in a surface reaction (e.g., chemisorption, oxidation, reduction, cycloaddition). The substrate, or portion of the substrate, is exposed sequentially to the two or more reactive compounds which are introduced into a reaction zone of a processing chamber.

Several metal and metal oxide materials, e.g., high Z materials, have been tested as EUV dielectric film hard masks (HM). As used herein, the term “dielectric” refers to an electrical insulator material that can be polarized by an applied electric field. Due to their chemistry, high Z films tends to react with oxygen and get oxidized in air over time. There is currently no efficient way to prevent this spontaneous surface oxidation and no feasible way to restore the high Z film surface. Due to this issue, it is hard to control dose-to-size for EUV exposure as well as to predict corresponding EUV lithography performance such as critical dimension (CD) and line width roughness (LWR). A high Z material underneath a metal oxide photoresist can reduce dose-to-size (DtS) in EUV processing. More specifically, the second electron induced by EUV light from a high Z film can significantly reduce the actual EUV dosage needed for lithography and lead to increase in throughput.

One or more embodiments is directed to a method of preventing spontaneous oxidation and restoring the high Z surface. Through the use of a reductive plasma treatment, like H* radicals in an advanced process chamber (APC) chamber, the metal-rich surface with dominating metallic state can be advantageously and effectively restored, leading to a predictable high Z metal composition, resulting in a more repeatable EUV lithographic process and addressing the concern of EUV performance shift such as dose-to-size, target CD and LWR. In one or more embodiments, the application of a reductive plasma to a naturally oxidized high Z film can advantageously restore a metal-rich surface and lead to repeatable EUV lithography performance.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

One or more embodiments of the disclosure are described with reference to the Figures. In one or more embodiments, a method of forming an EUV photoresist hard mask comprises treating a metal-rich layer on a substrate with a reductive plasma to form a metallic surface on the metal-rich layer, the metal-rich layer having a top portion comprising a metal oxide layer.

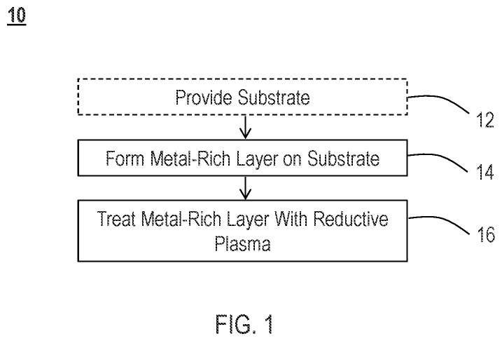

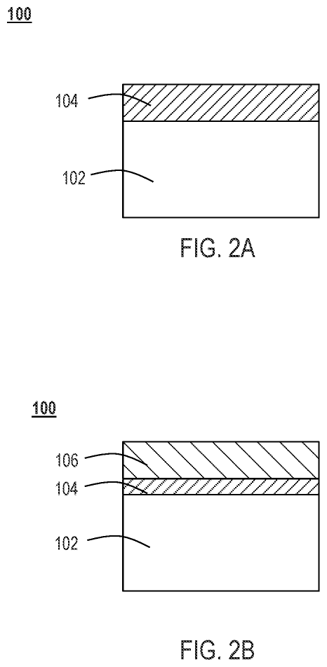

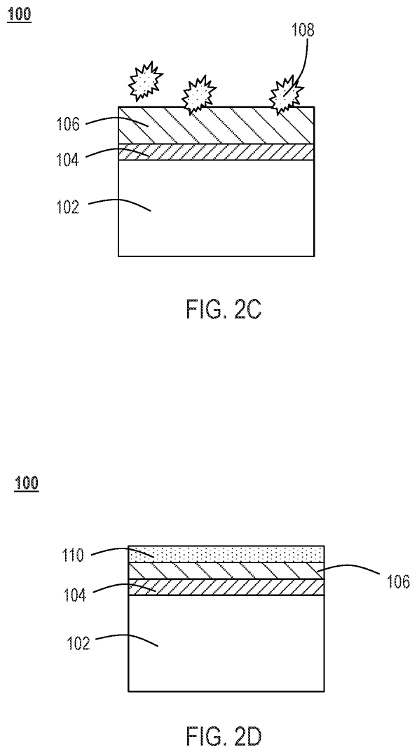

With reference to FIG. 1 and FIG. 2A, the method 10 starts at operating 12 by providing a substrate 102. As used in this specification and the appended claims, the term “provided” means that the substrate 102 or substrate surface is made available for processing (e.g., positioned in a processing chamber). The substrate 102 may be any substrate suitable for formation of an EUV photoresist hard mask.

At operation 14, a metal-rich layer 104 is formed on the substrate 102. In some embodiments, the metal-rich layer comprises a high Z metal. As used herein, the term “high Z” refers to chemical elements, e.g., metals, with a high atomic number (Z) of protons in the nucleus. In some embodiments, the high Z metal has an atomic number greater than 50.

In one or more embodiments, the metal-rich layer 104 comprises one or more of tin (Sn), indium (In), gallium (Ga), zinc (Zn), tellurium (Te), antimony (Sb), nickel (Ni), titanium (Ti), aluminum (Al), tantalum (Ta), bismuth (Bi), and lead (Pb). In more specific embodiments, the metal-rich layer comprises tin (Sn).

The metal-rich layer 104 may be formed by any suitable means known to the skilled artisan. In some embodiments, the metal-rich layer 104 may be deposited by one or more of physical vapor deposition, chemical vapor deposition, or atomic layer deposition.

In one or more embodiments, the metal-rich layer 104 may have any suitable thickness. In some embodiment, the metal-rich layer 104 has a first thickness in a range of from 10 Å to 100 Å.

With reference to FIG. 2B, the metal-rich layer 104 is oxidized in air and forms a metal oxide layer 106 on a top surface of the metal-rich layer 104. The metal oxide layer 106 comprises an oxide of the metal-rich layer 104. Thus, the metal oxide layer 106 comprises a high Z metal oxide. In one or more embodiments, the metal oxide layer 106 comprises one or more of tin oxide (SnOx), indium oxide (InOx), gallium oxide (GaOx), zinc oxide (ZnOx), tellurium oxide (TeOx), antimony oxide (SbOx), nickel oxide (NiOx), titanium oxide (TiOx), aluminum oxide (AlOx), tantalum oxide (TaOx), bismuth oxide (BiOx), and lead oxide (PbOx). In more specific embodiments, the metal oxide layer 106 comprises tin oxide (SnOx).

In one or more embodiments, when the metal oxide layer 106 forms on the metal-rich layer 104, the thickness of the metal-rich layer 104 decreases to a range of 10 Å to 50 Å. In one or more embodiments, the metal oxide layer 106 has a thickness in a range of from 20 Å to 100 Å.

With reference to FIG. 1 and FIGS. 2C and 2D, at operation 18, the metal-rich layer 104 and the metal oxide layer 106 are treated with a reductive plasma 108. Treatment with the reductive plasma 108 restores a metallic surface 110 on the metal-rich layer 104.

In some embodiments, the metallic surface 110 is substantially more metal-rich compared to metal-rich layer 104. As used herein, the term “substantially more” means that there is more than 1%, including more than 2%, more than 3%, more than 4%, and more than 5% of metal in metal-rich layer 104.

In one or more embodiments, when the metallic surface 110 formed on the metal-rich layer 104 has thickness in a range of from 10 Å to 50 Å. In one or more embodiments, treating the metal-rich layer 104 with the reducing plasma 108 reduces the thickness of the metal oxide layer 106 by 10 Å to 50 Å. In one or more embodiments, after treatment with the reducing plasma 108, the metal oxide layer 106 and the metallic surface 110 have a combined thickness in a range of from 20 Å to 100 Å.

In some embodiments, after seven days with treatment on high Z layer 104, the metal content of metallic surface is at least 40%. When there is no treatment with a reducing plasma 108, the metallic contact of the high Z layer 104 is about 35%. Thus, treatment with a reducing plasma can restore the metallic content of the high Z layer with minimal change in the thickness profile of the high layer 104.

In some embodiments, the reductive plasma 108 comprises one or more of hydrogen (H₂) and helium (He). In one or more embodiments, the reductive plasma 108 comprises at least 1% hydrogen, or at least 2% hydrogen, or at least 3% hydrogen, or at least 4% hydrogen, or at least 5% hydrogen, or at least 6% hydrogen, or at least 7% hydrogen, or at least 8% hydrogen, or at least 9% hydrogen, or at least 10% hydrogen, or at least 11% hydrogen, or at least 12% hydrogen, or at least 13% hydrogen, or at least 14% hydrogen, or at least 15% hydrogen, or at least 16% hydrogen, or at least 17% hydrogen, or at least 18% hydrogen, or at least 19% hydrogen. In one or more embodiments, the reductive plasma 108 comprises hydrogen in a range of from 1% to 20%. In one or more embodiments, helium (He) makes up the balance of the plasma.

In one or more embodiments, the reducing plasma may have any suitable flow rate. In one or more embodiments, reducing plasma has a plasma has a flow rate in a range of from 1 sccm to 1000 sccm, or in a range of from 1 sccm to 500 sccm, or in a range of from 1 sccm to 400 sccm, or in a range of from 1 sccm to 300 sccm, or in a range of from 1 sccm to 200 sccm, or in a range of from 1 sccm to 150 sccm, or in a range of from 1 sccm to 50 sccm, or in a range of from 1 sccm to 40 sccm, or in a range of from 1 sccm to 30 sccm, or in a range of from 1 sccm to 20 sccm, or in a range of from 1 sccm to 10 sccm.

In one or more embodiments, the plasma treatment may occur at any suitable pressure. In one or more embodiments, the device 100 is treated with the plasma at a pressure in a range of from 0.2 mTorr to less than 500 mTorr, or in a range of from 0.2 mTorr to 400 mTorr, or in a range of from 0.2 mTorr to 300 mTorr, or in a range of from 0.2 mTorr to 250 mTorr, or in a range of from 10 mTorr to 200 mTorr, or in a range of from 10 mTorr to 100 mTorr. In some embodiments, the pressure is greater than 50 mTorr, or greater than 60 mTorr, or greater than 70 mTorr, or greater than 80 mTorr, or greater than 90 mTorr, or greater than 100 mTorr.

In one or more embodiments, the plasma treatment may occur for any suitable period of time. In one or more embodiments, the device 100 is treated with the plasma for a period of time in a range of from 2 seconds to 10 minutes, or in a range of from 2 seconds to 5 minutes, or in a range of from 2 seconds to 4.5 min, or in a range of from 2 seconds to 3 minutes, or in a range of from 2 seconds to 2 minutes, or in a range of from 2 seconds to 1 minutes.

In one or more embodiments, the plasma treatment may occur any suitable temperature. In one or more embodiments, the plasma treatment occurs at a temperature in a range of from 10° C. to 400 ° C., including a range of from 20° C. to 200° C. In other embodiments, the plasma treatment occurs at ambient temperature or at room temperature.

In some embodiments, the plasma gas is flowed into the processing chamber and then ignited to form a direct plasma. In some embodiments, the plasma gas is ignited outside of the processing chamber to form a remote plasma.

In some embodiments, the plasma is an inductively coupled plasma (ICP). In some embodiments, the plasma is a conductively coupled plasma (CCP). In some embodiments, the plasma is a microwave plasma. In some embodiments, the plasma is generated by passing the plasma gas over a hot wire.

In one or more embodiments, the plasma treatment may occur at any suitable power. In one or more embodiments, the power is in a range of from 10 W to 2000 W, or in a range of from 100 W to 1500 W, or in a range of from 100 W to 1000 W, or in a range of from 100 W to 750 W.

Several well-known cluster tools which may be adapted for the present disclosure are the Olympia®, the Continuum®, and the Trillium®, all available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), plasma treatment, etch, pre-clean, chemical clean, thermal treatment such as RTP, plasma nitridation, degas, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed, and unloaded before another substrate is processed. The substrate can also be processed in a continuous manner, similar to a conveyer system, in which multiple substrates are individually loaded into a first part of the chamber, move through the chamber, and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support, and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A method of forming an EUV photoresist hard mask, the method comprising:
treating a metal-rich layer on a substrate with a reductive plasma to form a metallic surface on the metal-rich layer, the metal-rich layer having a top portion comprising a metal oxide layer, wherein the metal oxide layer remains after treatment and has a thickness that is less than the thickness of the metal oxide layer prior to treatment, and wherein the metal-rich layer, the metal oxide layer, and the metallic surface form the EUV photoresist hard mask.

2. The method of claim 1, wherein the metal-rich layer comprises one or more of tin (Sn), indium (In), gallium (Ga), zinc (Zn), tellurium (Te), antimony (Sb), nickel (Ni), titanium (Ti), aluminum (Al), tantalum (Ta), bismuth (Bi), and lead (Pb).

3. The method of claim 1, wherein the metal oxide layer comprises one or more of tin oxide (SnOx), indium oxide (InOx), gallium oxide (GaOx), zinc oxide (ZnOx), tellurium oxide (TeOx), antimony oxide (SbOx), nickel oxide (NiOx), titanium oxide (TiOx), aluminum oxide (AlOx), tantalum oxide (TaOx), bismuth oxide (BiOx), and lead oxide (PbOx).

4. The method of claim 1, wherein the metallic surface is substantially free of metal oxide.

5. The method of claim 1, wherein the metal-rich layer comprises tin (Sn) and the metal oxide layer comprises tin oxide (SnOx).

6. The method of claim 1, wherein the metal-rich layer has a thickness in a range of from 10 Å to 50 Å.

7. The method of claim 1, wherein the metal oxide layer has a thickness in a range of from 20 Å to 100 Å.

8. The method of claim 7, wherein treating the metal-rich layer with the reducing plasma reduces the thickness of the metal oxide layer by 10 Å to 50 Å.

9. The method of claim 8, wherein after treatment with the reducing plasma, the metal oxide layer and the metallic surface have a combined thickness in a range of from 20 Å to 100 Å.

10. The method of claim 1, wherein the metallic surface has a metallic content of at least 40% after seven days.

11. The method of claim 1, wherein the reducing plasma comprises from 1% to 20% hydrogen.

12. The method of claim 11, wherein the reducing plasma comprises at least 1% hydrogen and helium.

13. A method of forming an EUV photoresist hard mask, the method comprising:
forming a metal-rich layer on a substrate, the metal-rich layer having a thickness in a range of from 10 Å to 50 Å; the metal-rich layer having a top portion comprising a metal oxide layer with a thickness in a range of from 20 Å to 100 Å; and
treating the metal-rich layer with a reductive plasma to form a metallic surface on the metal-rich layer,
wherein the metal oxide layer remains after treatment and the thickness of the metal oxide layer is less than the thickness of the metal oxide layer prior to treatment, and
wherein the metal-rich layer, the metal oxide layer, and the metallic surface form the EUV photoresist hard mask.

14. The method of claim 13, wherein the metal-rich layer comprises one or more of tin (Sn), indium (In), gallium (Ga), zinc (Zn), tellurium (Te), antimony (Sb), nickel (Ni), titanium (Ti), aluminum (Al), tantalum (Ta), bismuth (Bi), and lead (Pb).

15. The method of claim 13, wherein the metal oxide layer comprises one or more of tin oxide (SnOx), indium oxide (InOx), gallium oxide (GaOx), zinc oxide (ZnOx), tellurium oxide (TeOx), antimony oxide (SbOx), nickel oxide (NiOx), titanium oxide (TiOx), aluminum oxide (AlOx), tantalum oxide (TaOx), bismuth oxide (BiOx), and lead oxide (PbOx).

16. The method of claim 13, wherein the metallic surface is substantially free of metal oxide.

17. The method of claim 13, wherein the metal-rich layer comprises tin (Sn) and the metal oxide layer comprises tin oxide (SnOx).

18. The method of claim 13, wherein treating the metal-rich layer with the reducing plasma reduces the thickness of the metal oxide layer by 10 Å to 50 Å.

19. The method of claim 18, wherein after treatment with the reducing plasma, the metal oxide layer and the metallic surface have a combined thickness in a range of from 20 Å to 100 Å.

20. The method of claim 1, wherein the reducing plasma comprises from 1% to 20% hydrogen.
